(19) United States
(12) Patent Application Publication
(10) Pub. No.: US 2005/0022720 A1
(43) Pub. Date: Feb. 3, 2005

(54) Acentric orthorhombic lanthanide borate crystals, method for making, and applications thereof

(76) Inventors: Joseph W. Kolis, Central, SC (US); Henry G. Giesber, Charlotte, NC (US)

Correspondence Address: LEIGH P. GREGORY;ATTORNEY AT LAW, PO BOX 168, CLEMSON, SC, 29633-0168, US

(21) Appl. No.: 10/631,401

(22) Filed: Jul. 31, 2003

(51) Int. Cl. C01F 17/00; C30B 1/00

(52) U.S. Cl. 117/2; 423/263

(57) ABSTRACT

Acentric lanthanide borate crystals having the general formula LnBO₃, wherein Ln is La, Ce, Pr, or Nd, are disclosed along with a hydrothermal method for forming such crystals. The crystals possess unique optical, non-linear optical, laser, electronic and other physical properties and, therefore, are useful in a wide variety of photonic devices.

### FIELD OF THE INVENTION

The present invention is directed to novel, acentric, orthorhombic lanthanide borate crystals having the formula LnBO₃, wherein Ln is selected from La, Ce, Pr and Nd, the hydrothermal method for making the crystals, and a wide variety of end-use applications. Specifically, when made by the present hydrothermal method, single crystals of a size sufficient for use in a variety of optical applications are formed.

### BACKGROUND OF THE INVENTION

It is well established that there is a constantly evolving need for new materials for optical devices and that the demands for quality are particularly high in the case of single crystals used in optical devices.

Recently there has been an increasing demand for materials that allow for the manipulation of light in the near UV, the UV and the deep UV. This region is roughly defined as light with wavelengths between 150 nm and 350 nm.

A particular need in this region is for coherent radiation with a completely solid state source. A fully solid state laser is desirable because such are generally compact, reliable, and rugged, with low power demands. In general, all-solid-state lasers capable of direct emission of coherent radiation in the UV region are not yet readily available.

An acceptable alternative is to use IR diode laser sources to excite lasing ions such as Nd:YAG which emit in the IR (e.g. 1064 nm) and then employ a non-linear optical crystal to generate second, third or fourth harmonics and double the frequency of the coherent radiation.

It is the acentricity of such crystals that enables them to alter coherent radiation of one or more frequencies by frequency doubling or sum frequency generation. Thus, for example, two photons of 1064 nm wavelength can be frequency doubled by an appropriate acentric crystal to form one photon of 532 nm radiation. This ability to frequency sum and divide is a very important source of new coherent radiation wavelengths. The ability to alter the frequency of coherent radiation is generally referred to as non-linear optical (NLO) behavior. The general requirements of suitable NLO crystals are that they must form in an acentric structure and should preferably exist in a polar structure for phase matching purposes. They should also be large enough (typically >1×2×2 mm) for polishing and orientation in devices. They should also be of high optical quality, namely containing few impurities, defects or twinning.

The most common inorganic crystals currently employed for NLO applications are K(TiO)PO₄ (commonly referred to as KTP) and LiNbO₃ (commonly referred to as LN). Both materials exhibit suitable NLO behavior in the visible region but their bandgaps are too narrow to exhibit satisfactory NLO behavior below 400 nm. Thus, in addition to the above-listed requirements, there is a great demand for UV NLO materials which have bandgaps below about 200 nm.

The primary class of compounds exhibiting this behavior are the metal borates. Borates generally have wide bandgaps, high optical damage thresholds, and show a marked tendency to crystallize in polar acentric space groups. Thus, borates have recently received attention as potential NLO materials in the near UV, UV and deep UV. Several borate materials have recently been employed in commercial applications in UV optical devices. These include beta barium borate (β-BaB₂O₄, commonly referred to as BBO), LiB₃O₅ (commonly referred to as LBO) and CsLiB₆O₁₀ (commonly referred to as CLBO). Several other borates have also been proposed as potential UV NLO materials including Sr₂Be₂B₂O₇ (commonly referred to as SBBO) and YCaOBO₃ (commonly referred to as YCOB). The primary limitation for full-scale employment of borate materials is based on crystal growth. Borates often do not melt congruently and, instead tend to form highly viscous melts. These factors inhibit growth of good quality single crystals. The primary methods of growth are typically flux or stop seeded solution techniques. However, it is difficult to grow large borate crystals of sufficient optical quality by either method.

Hydrothermal techniques are an excellent route to high quality single crystals for electro-optic applications. For example, all electronic grade quartz is grown commercially by the hydrothermal method. Further, KTP is grown by both flux and hydrothermal methods, and it is widely acknowledged by those familiar with the art that the hydrothermally grown product is generally of superior quality. The hydrothermal method involves the use of superheated water (liquid water heated above its boiling point) under pressure to cause transport of soluble species from a nutrient rich zone to a supersaturated growth zone. Generally, a seed crystal is placed in the growth zone to control the growth and supersaturation is achieved by the use of differential temperature gradients. The superheated fluid is generally contained under pressure, typically 5-30 kpsi, in a metal autoclave. Depending on the chemical demands of the system the autoclave can be lined with a nobel metal using either a fixed or floating liner. These general techniques are well known to those of ordinary skill in the art and have been used for the growth of other electro-optic crystals.

The lanthanide orthoborates (LnBO₃ where Ln is any lanthanide trivalent ion) are a known class of compounds and compounds of this formulation are even found as naturally occurring minerals. In addition, samples have been prepared in various labs using high temperature flux methods. In the case of the earliest lanthanides (where Ln is La, Ce, Pr, or Nd), the structure of all of these other samples of this formulation LnBO₃ is described as having a centrosymmetric structure, isostructural with aragonite CaCO₃ and is reported as existing in the centric space group Pnma.

Additionally, many trivalent lanthanide ions display active emission of coherent radiation when doped into appropriate hosts. Upon pumping with an appropriate pump source (i.e. diode, solid state, gas, or excimer lasers, or arc, mercury or other lamp), the lanthanide ions exhibit emission of coherent radiation (laser emission). The coherent radiation emission properties of the various trivalent lanthanide lasing ions are well described in the literature. Prior art hosts are typically metal oxide or fluoride solids that contain trivalent metals that can be substituted in small quantities with the trivalent lanthanide ion of choice. The necessary and desirable characteristics of hosts are described in the literature, and are well known to practitioners of the art. Specific examples of such materials are Nd:YCOB and Nd:GbCOB.

### SUMMARY OF THE INVENTION

It has been found in accordance with the present invention that certain lanthanide borates are well suited both for synthesis of new forms of matter and for growth of optical-quality single crystals of these new forms of matter. Specifically, the present invention is directed to the hydrothermal synthesis and crystal growth of a new form of matter with considerable potential for near UV, UV and deep UV optical applications.

Specifically, the present invention is directed to a hydrothermal synthesis of single crystals of compounds of the formula LnBO₃ where Ln is La, Ce, Pr, or Nd that form in a new structure type that is polar acentric. The acentricity is significant because the compounds can function in NLO applications as described above. The polar nature of the new materials means that they can phase match and act as a birefringent. The new materials have a very wide bandgap (at least 190 nm) making them suitable for a number of deep UV NLO applications. They also have excellent thermal and optical stability.

Further, the present materials can be altered by changing the identity of the host lanthanide ion by at least 20% or greater. Therefore, the various new materials can form a wide number of formulations containing laser ions. Accordingly, LaBO₃, for example, can serve as a host and can be doped with from about 1% to about 20% of Nd³⁺ to form Nd:LaBO₃. These doped compounds can emit coherent radiation upon pumping with a wide variety of near IR sources. When an acentric material can act as both a host for a laser emitter and a NLO material it is one of a rare but highly desirable class of compounds called self-frequency doublers. Such highly functional materials have many potential applications as compact solid state UV and visible lasers.

Thus, in one aspect the present invention is directed to an acentric, polar, orthorhombic lanthanide borate crystal of the formula LnBO₃, where Ln is selected from La, Ce, Pr and Nd. The present crystal belongs to a C-centered space group and to the mm2 point group. Therefore, it exhibits non-linear optical properties.

In another aspect the present invention is directed to an acentric, polar, orthorhombic lanthanide borate crystal of the formula Ln_{y}LnₓBO₃, where Lnₓ is selected from La, Ce, Pr and Nd, and where Ln_{y} is selected from La, Ce, Pr, Nd, Y, Pm, Sm, Eu, Gd, Tb, Dy, Ho, Er, Tm, Yb, Lu and Cr and mixtures thereof, and where Lnₓ and Ln_{y} are differing trivalent ions and the molar ratio of Ln_{y}:Lnₓ is from about 0.05:99.95 to about 20:80. Such crystal is appropriate for use as an active gain medium for a laser. Additionally, as the crystal exhibits non-linear optical properties it functions as a self-frequency doubler.

In yet another aspect the present invention is directed to a method for growing a single orthorhombic lanthanide borate crystal which includes the step of reacting B₂O₃ and Ln₂O₃, where Ln is selected from La, Ce, Pr and Nd, in an aqueous solution at a temperature of from about 350° C. to about 600° C. and at a pressure of from about 8 kpsi to about 45 kpsi. Optionally, the method involves reacting B₂O₃, (Lnₓ)₂O₃, and (Ln_{y})₂O₃ where Lnₓ is selected from La, Ce, Pr, and Nd and where Ln_{y} is selected from La, Ce, Pr, Nd, Y, Pm, Sm, Eu, Gd, Tb, Dy, Ho, Er, Tm, Yb, Lu and Cr and mixtures thereof, where Lnₓ and Ln_{y} are differing trivalent ions and the molar ratio of (Lnₓ)₂O₃ and (Ln_{y})₂O₃ to B₂O₃ is 1:1 and wherein the molar ratio of (Lnₓ)₂O₃ to (Ln_{y})₂O₃ is from about 99.95:0.05 to about 80:20.

### BRIEF DESCRIPTION OF THE FIGURES OF THE DRAWING

The accompanying drawings, which are incorporated in and constitute a part of the specification, illustrate presently preferred embodiments of the present invention and, together with the general description given above and the detailed description of the preferred embodiments given below, serve to explain the principles of the present invention.

FIG. 1 schematically illustrates an autoclave loaded for crystal growth under hydrothermal conditions;

FIG. 2A is a computer generated representation of the structure of PrBO₃ in accordance with the present invention obtained by single crystal X-ray diffraction, showing the planes formed by the layers of planar borate groups, where the lanthanide ions are located between the borate layers but shifted to one side;

FIG. 2B is a computer generated representation of the structure of PrBO₃ in accordance with the present invention obtained by single crystal X-ray diffraction, showing the borate groups with the lanthanide ions arranged throughout;

FIG. 3 is an absorption spectrum of a single crystal of PrBO₃ made in accordance with Example 1;

FIG. 4 is an emission spectrum of PrBO₃ made in accordance with Example 1, which demonstrates the crystal's potential for serving as a host of lasing behavior;

FIG. 5 is a fluorescence spectrum of an Er:Yb doped LaBO₃ crystal prepared in accordance with Example 3; and

FIG. 6 schematically illustrates a silver tube with seed crystals suspended from a ladder for the growth of larger crystals in accordance with the present invention by a transport growth technique.

### DETAILED DESCRIPTION OF THE PREFERRED EMBODIMENTS

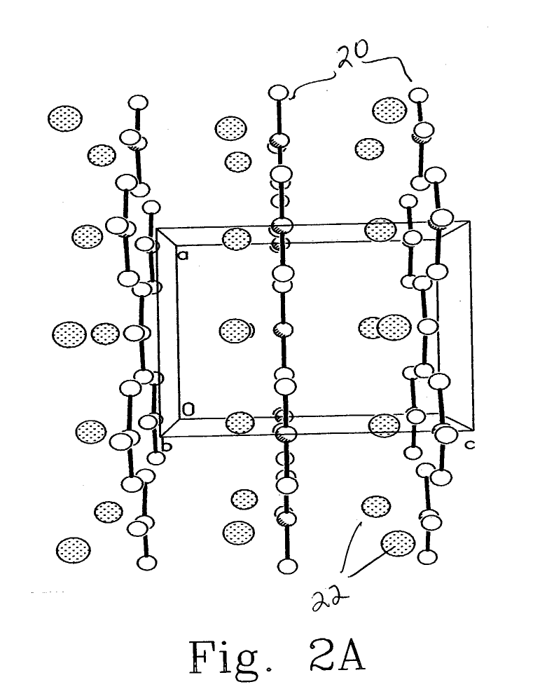

The present invention is directed to an acentric, polar, orthorhombic lanthanide borate crystal of the formula LnBO₃, where Ln is selected from La, Ce, Pr and Nd, which is of sufficient size and quality for use in a variety of optical devices and applications. The new class of single crystals described herein is acentric, belonging to a C-centered space group, specifically Cmc2₁. Since the crystal is acentric, it may be used in non-linear optical applications and devices. These applications include but are not limited to frequency doubling tripling and quadrupling, sum frequency generation, optical parametric oscillation and amplification and any other desirable non-linear behavior. The present crystals also have a polar structure, providing them with the ability to phase match for coherent radiation emission. The general structure of the present crystals is illustrated at FIGS. 2A and 2B, which are computer generated representations of the structure of PrBO₃ in accordance with the present invention obtained by single crystal X-ray diffraction. FIG. 2A shows the planes formed by the layers of planar borate groups 20, where the lanthanide ions 22 are located between the borate layers but shifted to one side. FIG. 2B shows the borate groups 20 with the lanthanide ions 22 arranged throughout.

Generally, the inherent bandgap of any NLO crystal should be substantially greater than the energy of coherent radiation being emitted. Thus a NLO crystal that frequency doubles 1064 nm to 532 nm radiation must have a bandgap substantially larger than that of 532 nm radiation or all of the photons being produced will simultaneously get absorbed. This limitation is significant for the most common commercial materials, LiNbO₃ and KTP, as those materials possess bandgaps which are not much larger than 3.2 eV. For near UV, UV and deep UV applications bandgaps are required to be much larger, typically greater than 5 eV. This limitation led to the development of new acentric borates, BBO and LBO, discussed in the Background section above, which each have bandgaps greater than 5 eV. The bandgaps of the crystals of the present invention are particularly wide, greater than 6.5 eV. Thus, the present crystals may be employed in applications for which other electro-optical materials are not suitable. These include, but are not limited to visible, UV, and deep UV NLO applications. Specifically, the present crystals can frequency-double coherent radiation to yield blue, violet, UV and deep UV laser emission.

Further, the present invention is directed to an optical parametric oscillator, which contains a lanthanide crystal as defined herein.

In another aspect the present invention is directed to doped crystals, which may serve as an active, gain medium for a laser. Specifically, such doped crystals have the general formula Ln_{y}LnₓBO₃, where Lnₓ is selected from La, Ce, Pr and Nd, and where Ln_{y} is selected from La, Ce, Pr, Nd, Y, Pm, Sm, Eu, Gd, Tb, Dy, Ho, Er, Tm, Yb, Lu and Cr and mixtures thereof, and where Lnₓ and Ln_{y} are differing trivalent ions and the molar ratio of Ln_{y}:Lnₓ is from about 0.05:99.95 to about 20:80. That is, each of the present crystals can be doped with one or more of any of the known lanthanide trivalent ions or Cr³⁺. Given this ability, a wide variety of new laser crystals can be created with the general formula Ln_{y}LnₓBO₃ (where x+y=1). Thus, if only one dopant is employed, 64 different dopant:host crystals may be formed, and the number of different crystals goes up exponentially as more dopants are employed.

Additionally, as the crystals of the present invention exhibit non-linear optical properties, each lasing crystal functions as a self-frequency doubler. That is, since the crystals are acentric and can also act as hosts for activator ions, the same crystals that generate laser radiation can double the emission radiation. Accordingly, these materials can find application as solid state lasers emitting near UV, UV, or deep UV coherent radiation. A major advantage of such devices is that they simplify and decrease the size of the laser, since multiple applications are being performed by one crystal. Thus, the device can be smaller and more rugged. Accordingly, the present invention greatly expands the number of unique, self-frequency doubling crystals available for use in laser applications.

Additionally, the ability to grow polar acentric single crystals of a new material with high optical quality, wide bandgap and desirable physical characteristics leads to suitability for other end-use applications. Specifically, the polar nature of the structure allows for use in applications including birefringence, filtering, double refraction, polarization, wave plates, prisms and retarders. In addition, the crystals can be used as windows and lenses in UV and deep UV applications. The polar nature of the structure also allows for the use in ferroelectric and electro-optic dependent devices such as modulators and switches.

Specifically, crystals in accordance with the present invention demonstrate electro-optic properties, including piezoelectric, magnetoelectric, ferroelectric, acousto-optic, and pyroelectric responses. Thus, the present crystals may be employed in the development of devices, which act as electro-optic , acousto-optic, pyroelectric, ferroelectric and magneto-optic modulators, switches and detectors.

Further, the crystals and doped crystals in accordance with the present invention are very hard, display a wide variety of attractive colors and appearance and are birefringent. As such they can also be employed in ornamental applications, such as synthetic gems. The hardness of these materials also allows for their application in precision grinding and polishing applications and as abrasive materials.

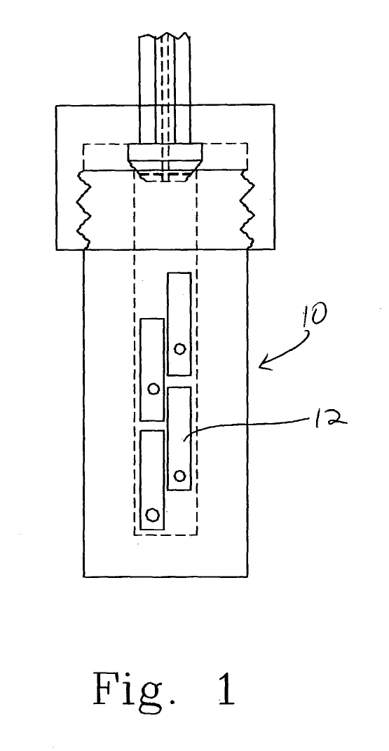

In yet another aspect the present invention is directed to a method for growing the present inventive crystal which includes the step of reacting B₂O₃ and Ln₂O₃, where Ln is selected from La, Ce, Pr and Nd, in an aqueous solution at a temperature of from about 350° C. to about 600° C. and at a pressure of from about 8 kpsi to about 45 kpsi. By this method, water containing alkali metal hydroxide sufficient to create an OH⁻ concentration between 1×10⁻³ M and 10 M is heated to temperatures between 350-600° C. at pressures between 8 and 45 kpsi. Suitable hydroxide sources include LiOH, NaOH, KOH, RbOH, CsOH, and NH₄OH, among others. The two reactants are present in equimolar amounts or an excess of B₂O₃ is employed. FIG. 1 schematically represents a preferred autoclave 10 employed in achieving the temperature and pressure conditions necessary for the present reaction. The reactants are added to a silver tube 12 having a diameter of 0.25 in and a length of 2 in. Then, the hydroxide source is added to the tube and it is welded shut. The sealed tube or ampoule is placed in the autoclave which has an internal diameter of ½ in and a depth of 6 in. Water is added to the autoclave, filling approximately 75% of the remaining free volume of the autoclave. The autoclave is sealed shut using a cold seal. The sealed autoclave containing the sealed silver ampoule is placed in a tube furnace oriented in a vertical position. The furnace is heated to the desired elevated temperature and held at that temperature for an extended period of time. The water in the autoclave expands at this elevated temperature to create the desired elevated pressure. Thereafter, the autoclave is removed from the oven and cooled in a stream of air.

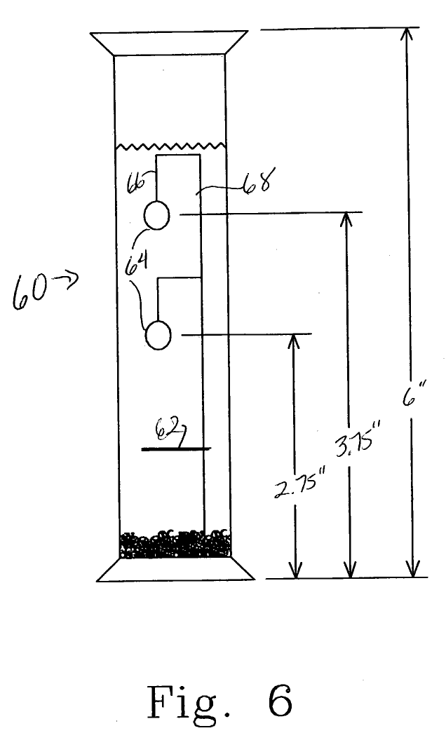

Alternatively, employing the same starting materials and similar reaction conditions, large crystals of LnBO₃ are grown from seed crystals, which have been formed by the present inventive method. By such hydrothermal growth transport method, a temperature gradient of between 10° and 100° C. is maintained between a warmer nutrient zone and a cooler growth zone. The aqueous growth medium may include an aqueous hydroxide selected from, for example, LiOH, NaOH, KOH, RbOH, CsOH, and NH₄OH; an aqueous carbonate selected from, for example Li₂CO₃, Na₂CO₃, K₂CO₃, Rb₂CO₃, Cs₂CO₃, and (NH₄)₂CO₃, and mixtures thereof; and soluble anions selected from, for example, nitrate, fluoride, chloride and combinations thereof. The apparatus for performing the hydrothermal growth transport method is shown in FIG. 6 in which LnBO₃ powder is in a silver tube 60 of dimensions ⅜ in by 6 in. A silver baffle 62 with three small holes in it is placed 1.25 in above the bottom of the tube. Two single crystals 64 of LnBO₃ prepared in accordance with the present invention, each approximately 2×2×4 mm, serve as seeds. Holes are drilled in the crystals and they are hung by silver thread 66 on a small silver ladder 68 placed within the tube. The two seed crystals are hung 2.75 in and 3.75 in above the bottom of the tube, respectively. Preferably, the aqueous hydroxide is added to the tube and fills about 80% of the remaining volume of the tube. The tube is welded shut and placed in an autoclave with a cold seal and a ½ in by 8 in opening. An amount of water sufficient to occupy 80% of the remaining free volume is added and the autoclave sealed and placed in an upright tube furnace. The autoclave is heated with a temperature gradient. After an extended period of time, the autoclave is cooled, opened and the silver tube opened.

Optionally, in order to form doped, lasing crystals in accordance with the present invention, the present method involves reacting B₂O₃, (Lnₓ)₂O₃, and (Ln_{y})₂O₃ where Lnₓ is selected from La, Ce, Pr, and Nd and where Ln_{y} is selected from La, Ce, Pr, Nd, Y, Pm, Sm, Eu, Gd, Tb, Dy, Ho, Er, Tm, Yb, Lu and Cr and mixtures thereof, where Lnₓ and Ln_{y} are differing trivalent ions and the molar ratio of (Lnₓ)₂O₃ and (Ln_{y})₂O₃ to B₂O₃ is 1:1 and wherein the molar ratio of (Lnₓ)₂O₃ to (Ln_{y})₂O₃ is from about 99.95:0.05 to about 80:20.

The following Examples are presented in order to clarify, and not restrict, the present invention.

### EXAMPLE 1

Acentric, orthorhombic PrBO₃ has been formed by spontaneous nucleation from a hydrothermal reaction. In accordance with the present invention, 16 mg B₂O₃ (supplied by Aldrich, St. Louis, Mo.) and 38 mg Pr₂O₃ (supplied by Alfa Aesar, Ward Hill, Mass.) were added to a silver tube having a diameter of 0.25 in and a length of 2 in. Then, 0.40 ml of a 10M solution of NaOH was added to the tube and it was welded shut. The sealed tube or ampoule was placed in an autoclave with an internal diameter of ½ in and a depth of 6 in. Water was added to the autoclave, filling approximately 75% of the remaining free volume of the autoclave. The autoclave was sealed shut using a cold seal. A schematic representation of a fully loaded autoclave is set forth in FIG. 1. The sealed autoclave containing the sealed silver ampoule was placed in a tube furnace oriented in a vertical position. The furnace was heated to 550° C. and held at that temperature for three days. The water in the autoclave expanded at this temperature to create a pressure of approximately 30 kpsi. After three days of continuous heating, the autoclave was removed from the oven and cooled in a stream of air.

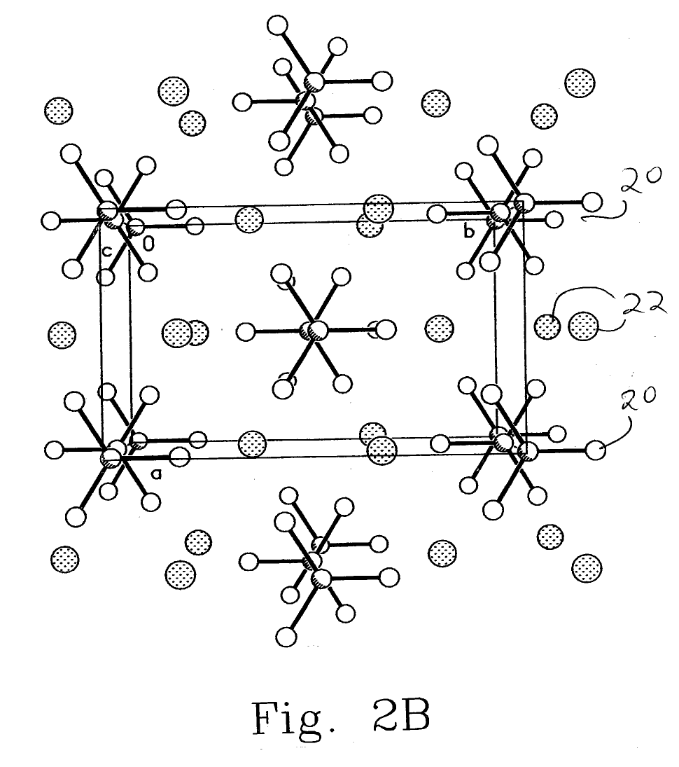

After the autoclave cooled to room temperature it was opened, the silver tube cut open with pliers and the crystals of PrBO₃ were isolated as green columns of approximate dimension 5×2×2 mm. The identity of the crystals was confirmed by single crystal x-ray diffraction, shown schematically in FIGS. 2A and 2B, which determined the unit cell of the material to be orthorhombic in space group Cmc21 with a=5.0650(10) Å, b=8.1300(16) Å, c=5.7690(12) Å. This unit cell is considerably different from the aragonite type reported for the naturally occurring material. The single crystal data was collected on a Nicolet P3 diffractometer with MoKα radiation. There were 751 reflections observed in a sphere of 2O=60°, of which 390 were unique. The structure was refined to an R factor of 1.81% (Rw=4.86%). Centering was clearly indicated by extinctions, and intensity statistics indicate acentricity. The refined Flack parameter was 0.17(6). When the inverted structure was refined, the Flack parameter went to 0.96(13) clearly indicating acentricity. The optical properties of PrBO₃ were determined with the absorption spectra 30 given in FIG. 3. It can be noted that the spectrum was taken to 190 nm, the limit of the available instrumentation and the band edge had not yet appeared, meaning that the bandgap was greater than 6 eV. The IR spectrum (obtained with a Nicolet Magna-FTIR Spectrometer 550) shows that the phonon band edge occurred at 1300 cm⁻¹. A standard Kurtz experiment using a pulsed Nd:YAG laser source demonstrated the conversion of 1064 nm coherent radiation to 532 nm radiation, confirming the usefulness of the material in second harmonic generation.

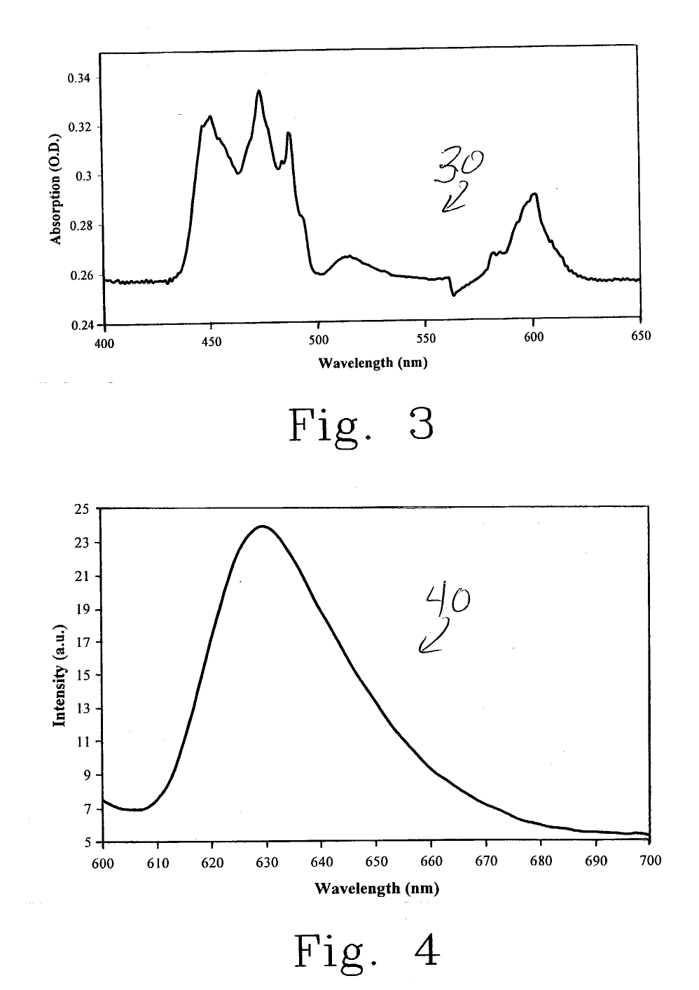

FIG. 4 is an emission spectrum 40 of the PrBO₃ crystal resulting from excitation into the 488 absorption band, indicating the presence of Pr³⁺ in the material and demonstrating the potential for borates of the structure type to act as hosts for lasing behavior.

### EXAMPLE 2

High quality single crystals of LaBO₃ doped with an active lasing ion, Europium, were formed by a method similar to that described in Example 1, above, yielding crystals of the general formula Eu_{0.05}La_{0.95}BO₃. For purposes of the present example the starting materials were 37 mg La₂O₃ (supplied by Alfa Aesar), 3 mg Eu₂O₃ (supplied by Strem, Newburyport, Mass.), and 16 mg B₂O₃ solids. Once again single crystals of high quality and size (approximately 4×4×1 mm) were isolated. The elemental ratios were confirmed using EDAX scanning electron microscopy (on an EDAX 4700 FE SEM with Oxford EDX attachment). Further, the luminescence spectrum of the Eu_{0.05}La_{0.95}BO₃ crystals (obtained with a SPEX Fluorolog II) displayed characteristic emissions at 592 nm for the 5D0→7F1 transition and five emissions at 612 nm, 615 nm, 618 nm, 620 nm, and 623 nm for the 5D0→7F2 transitions.

### EXAMPLE 3

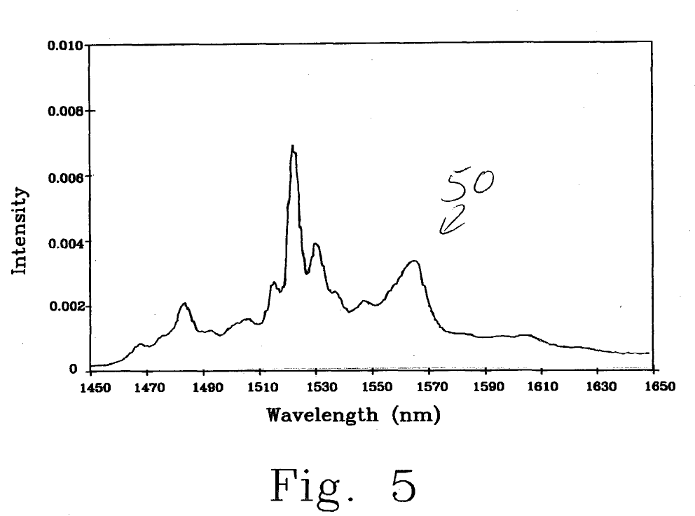

A ternary doped single crystal of the formula Er_{0.005}Yb_{0.05}La_{0.945}BO₃ was prepared by the method set forth in Example 1, except the starting materials employed were 37 mg La₂O₃, 16 mg B₂O₃, 2 mg Er₂O₃ (supplied by Strem), and 10 mg Yb₂O₃ (supplied by Strem). As in Example 2, high quality single crystals having dimensions of approximately 4×4×1 mm were isolated. The crystals were characterized by powder X-ray diffraction (using a Scintag XDS 2000 θ-θ powder diffractometer equipped with Cu Kα radiation (λ1.5406 Å)) and found to be identical in structure to the LaBO₃ crystals of Example1. The elemental composition described above was determined by EDAX scanning electron microscopy. The crystals also displayed the characteristic luminescence spectrum containing numerous sharp peaks centered around 1525 nm, as is shown in the spectrum 50 of FIG. 5.

### EXAMPLE 4

Acentric, rhombohedral PrBO₃ was formed by hydrothermal transport of PrBO₃ powder. A sample of PrBO₃ powder was prepared by heating a ground sample of equal amounts of B₂O₃ and Pr₂O₃ from commercially available sources. The materials were ground together in a mortar and pestle to a fine powder. The powdered material was placed in a platinum crucible and heated to 900° C. for 10 hours and then cooled to room temperature. The identity of the powder as orthorhombic PrBO₃ was confirmed by X-ray powder diffraction. One hundred twenty mg of the resultant powder was placed in a silver tube of dimensions ⅜ in by 6 in. A silver baffle with three small holes in it was placed 1.25 in above the bottom of the tube. Two single crystals of PrBO₃ prepared in accordance with Example 1, each approximately 2×2×4 mm, were chosen to serve as seeds. Holes were drilled in the crystals and they were hung by silver thread on a small silver ladder placed within the tube. The two seed crystals were hung 2.75 in and 3.75 in above the bottom of the tube, respectively, as is shown in FIG. 6. A 6 ml sample of a solution of 0.1M NaOH was added to the tube, which filled about 80% of the remaining volume of the tube. The tube was welded shut and placed in an autoclave with a cold seal and a ½ in by 8 in opening. An amount of water sufficient to occupy 80% of the remaining free volume was added and the autoclave sealed and placed in an upright tube furnace. The autoclave was heated with a temperature gradient such that the temperature was 580° C. at the bottom, or dissolving zone, while the top of the autoclave, or growth zone, was heated to 530° C. After four days of heating, the autoclave was cooled, opened and the silver tube opened. The crystals were removed and weighed. They showed a weight gain of 25%, confirming that the crystals can be grown by hydrothermal transport as is standard for materials like KTP and α-quartz.

Although the present invention has been described in connection with the preferred embodiments, it is to be understood that modifications and variations may be utilized without departing from the principles and scope of the invention, as those skilled in the art will readily understand. Accordingly, such modifications may be practiced within the scope of the following claims. Moreover, Applicants hereby disclose all subranges of all ranges disclosed herein. These subranges are also useful in carrying out the present invention.

1. An acentric, polar, orthorhombic lanthanide borate crystal comprising the formula LnBO₃, wherein Ln is selected from the group consisting of La, Ce, Pr and Nd.

2. The lanthanide borate crystal set forth in claim 1 wherein the crystal belongs to a C-centered space group.

3. The lanthanide borate crystal set forth in claim 2 wherein the crystal belongs to the mm2 point group.

4. The lanthanide borate crystal set forth in claim 1 wherein the crystal exhibits non-linear optical properties.

5. An acentric, polar, orthorhombic lanthanide borate crystal comprising the formula Ln_{y}LnₓBO₃, wherein Lnₓ is selected from the group consisting of La, Ce, Pr and Nd, and wherein Ln_{y} is selected from the group consisting of La, Ce, Pr, Nd, Y, Pm, Sm, Eu, Gd, Tb, Dy, Ho, Er, Tm, Yb, Lu and Cr and mixtures thereof, wherein Lnₓ and Ln_{y} are differing trivalent ions and wherein the molar ratio of Ln_{y}:Lnₓ is from about 0.05:99.95 to about 20:80.

6. The lanthanide borate crystal set forth in claim 5 comprising an active gain medium for a laser.

7. The lanthanide borate crystal set forth in claim 6 wherein the lasing crystal comprises a self-frequency doubler.

8. A method for growing a single orthorhombic lanthanide borate crystal comprising:
reacting B₂O₃ and Ln₂O₃, wherein Ln is selected from the group consisting of La, Ce, Pr and Nd, in an aqueous solution at a temperature of from about 350° C. to about 600° C. and at a pressure of from about 8 kpsi to about 45 kpsi.

9. The method set forth in claim 8 wherein the step of reacting B₂O₃ and Ln₂O₃ comprises reacting B₂O₃, (Lnₓ)₂O₃, and (Ln_{y})₂O₃ wherein Lnₓ is selected from the group consisting of La, Ce, Pr, and Nd and wherein Ln_{y} is selected from the group consisting of La, Ce, Pr, Nd, Y, Pm, Sm, Eu, Gd, Tb, Dy, Ho, Er, Tm, Yb, Lu and Cr and mixtures thereof, wherein Lnₓ and Ln_{y} are differing trivalent ions and wherein the molar ratio of (Lnₓ)₂O₃ and (Ln_{y})₂O₃ to B₂O₃ is 1:1 and wherein the molar ratio of (Lnₓ)₂O₃ to (Ln_{y})₂O₃ is from about 99.95:0.05 to about 80:20.
